(19) United States
(12) Patent Application Publication
(10) Pub. No.: US 2026/0129872 A1
(43) Pub. Date: May 7, 2026

(54) MEMORY SYSTEM

(71) Applicant: SK hynix Inc., Icheon-si (KR)

(72) Inventor: Seong Ju LEE, San Jose, CA (US)

(21) Appl. No.: 18/934,803

(22) Filed: Nov. 1, 2024

(51) Int. Cl. H10B 80/00; H01L 25/065

(52) U.S. Cl. CPC H10B 80/00; H10W 90/00; H10W 90/24; H10W 90/752; H10W 90/754

(57) ABSTRACT

A memory system comprises a substrate having a first substrate side and a second substrate side; and a memory media including a first memory stack mounted over the substrate. The substrate includes first signal substrate pads. The first signal substrate pads are closer to the first substrate side. The first memory stack includes a first memory chip and a second memory chip. The first memory chip includes first outer chip pads and first inner chip pads disposed adjacent to a first chip side. The second memory chip includes second outer chip pads and second inner chip pads disposed adjacent to a first chip side of the second memory chip. The corresponding first signal substrate pads, the corresponding first inner chip pads, and the corresponding second inner chip pads are electrically connected to each other.

### BACKGROUND

### 1. Field

Embodiments of the present disclosure relate to a memory system including a controller and a memory stack.

### 2. Description of the Related Art

Various memory systems for high-speed operations and low power consumption are being studied.

### SUMMARY

An embodiment of the present disclosure provides a memory system including a controller and a memory stack.

An embodiment of the present disclosure provides a memory system in which a controller and a memory chip directly communicate with each other through channels that are arranged in parallel without a SERDES (serializer/de-serializer).

An embodiment of the present disclosure provides a memory system having a memory stack in which all stacked memory chips operate in a slave mode.

An embodiment of the present disclosure provides a method for operating a memory chip that functions as a master chip in a slave mode.

In accordance with an embodiment of the present disclosure, a memory system comprises a substrate having a first substrate side and a second substrate side, that is opposite to the first substrate side; and a memory media including a first memory stack mounted over the substrate. The substrate includes first signal substrate pads disposed over a surface of the substrate. The first signal substrate pads are closer to the first substrate side than the second substrate side. The first memory stack includes a first memory chip and a second memory chip that is offset-stacked over the first memory chip. The first memory chip includes first outer chip pads and first inner chip pads. The first outer chip pads and first inner chip pads are disposed adjacent to a first chip side of the first memory chip. The first chip side of the first memory chip is closer to the first substrate side than the second substrate side. The first outer chip pads are disposed closer to the first chip side of the first memory chip than the first inner chip pads. The second memory chip includes second outer chip pads and second inner chip pads. The second outer chip pads and the second inner chip pads are disposed adjacent to a first chip side of the second memory chip. The first chip side of the second memory chip is closer to the first substrate side than the second substrate side. The second outer chip pads are disposed closer to the first chip side of the second memory chip than the second inner chip pads. The corresponding first signal substrate pads, the corresponding first inner chip pads, and the corresponding second inner chip pads are electrically connected to each other.

In accordance with another embodiment of the present disclosure, a memory system comprises a memory controller; an interface circuit; DDR PHY Interface (DFI) channels between the memory controller and the interface circuit; a memory media; and global input/output (GIO) channels between the interface circuit and the memory media. The memory media includes a first memory stack and a second memory stack that are mounted over a substrate. Each of the first memory stack and the second memory stack includes a first memory chip and a second memory chip that are offset-stacked over the substrate. The substrate includes first signal substrate interconnections and second signal substrate interconnections electrically connected to the global input/output channels, respectively; first signal substrate pads electrically connected to the first signal substrate interconnections; and second signal substrate pads electrically connected to the second signal substrate interconnections. Each of the first and second memory chips includes outer chip pads and inner chip pads that are disposed adjacent to a first chip side of each of the first and second memory chips.

### BRIEF DESCRIPTION OF THE DRAWINGS

FIG. 1 is a block diagram schematically illustrating an electronic system in accordance with an embodiment of the present disclosure.

FIG. 2 is a block diagram schematically illustrating a Compute eXpress Link (CXL) controller in accordance with an embodiment of the present disclosure.

FIG. 3 is a block diagram schematically illustrating a memory media in accordance with an embodiment of the present disclosure.

FIG. 4 is a block diagram schematically illustrating data channels for data communication in a memory system in accordance with an embodiment of the present disclosure.

FIGS. 5A and 5B are top and side views schematically illustrating one memory stack in accordance with an embodiment of the present disclosure.

FIG. 6 is a circuit diagram schematically illustrating a memory system in accordance with an embodiment of the present disclosure.

FIG. 7 illustrates a memory chip operating in a slave mode in accordance with embodiments of the present disclosure.

### DETAILED DESCRIPTION

Embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

According to embodiments of the present disclosure, ‘communicate’ may be interpreted as meaning transmitting and receiving electrical signals. In other words, ‘not communicate’ may be interpreted as meaning not transmitting and receiving electrical signals.

According to embodiments of the present disclosure, descriptions of ‘close to or adjacent to the first substrate/chip side’ can be interpreted as ‘closer to the first substrate/chip side than the second substrate/chip side’, and ‘close to or adjacent to the second substrate/chip side’ can be interpreted as ‘closer to the second substrate/chip side than the first substrate/chip side’.

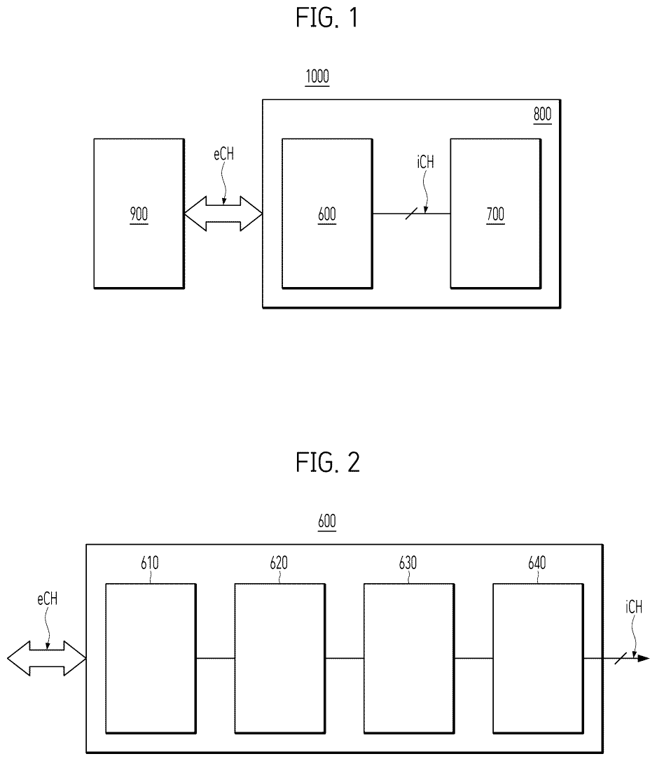

FIG. 1 is a block diagram schematically illustrating an electronic system 1000 in accordance with an embodiment of the present disclosure. Referring to FIG. 1, the electronic system 1000 may include a host 900 and a memory system 800.

The host 900 may include one of a server, a processor, and a computing system. The processor may include at least one processing unit among a Central Processing Unit (CPU), a Graphic Processing Unit (GPU), an Application Processor (AP), a Micro Control Unit (MCU), or a Neural Processing Unit (NPU). The host 900 and the memory system 800 may electrically communicate with each other through external channels eCH. According to an embodiment of the present disclosure, the external channels eCH may include Compute eXpress Link (CXL) channels.

The memory system 800 may include a CXL controller 600 and a memory media 700. The CXL controller 600 may receive various signals and data from the host 900 and transmit them to the memory media 700, and may receive data from the memory media 700 and transmit data to the host 900. The memory system 800 may further include internal channels iCH that electrically connect the CXL controller 600 to the memory media 700. The CXL controller 600 and the memory media 700 may electrically communicate with each other through the internal channels iCH. The internal channels iCH may include data channels that transmit chip select signals, data strobe signals, and data signals. The internal channels iCH may further include a CA (command/address) channel that electrically connects the CXL controller 600 and the memory media 700 to each other in the memory system 800.

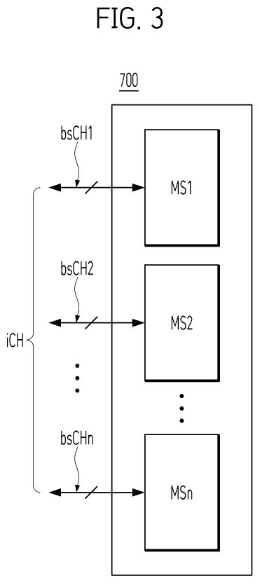

FIG. 2 is a block diagram schematically illustrating the CXL controller 600 in accordance with an embodiment of the present disclosure. Referring to FIG. 2, the CXL controller 600 may include an external interface circuit 610, a CXL block 620, a memory controller 630, and an internal interface circuit 640. The external interface circuit 610 may include a PCIe (Peripheral Component Interconnect express), a SERDES (serializer/de-serializer) and a transceiver TX/RX. The CXL block 620 may provide a memory access environment of a low latency and a high-bandwidth. According to an embodiment of the present disclosure, the CXL block 620 may be a CXL 2.0. The memory controller 630 may transmit and receive various signals and data for operating the memory media 700. The memory controller 630 and the memory media 700 may transmit and receive all data signals in a parallel form through the internal channels iCH at the same time.

The CXL block 620 may store base addresses of Base Address Registers (BARs) and a Host-managed-Device-Memory (HDM) in a predetermined space. The CXL block 620 may convert a CXL packet, which is received through the external interface circuit 610, into a memory request and transmit the memory request to the memory controller 630. The CXL block 620 may generate an internal memory address based on the base address of the HDM included in the CXL packet, and may transmit a request for the generated internal memory address to the memory controller 630. Subsequently, the CXL block 620 may receive the result obtained from the processing by the memory controller 630, convert the result into a CXL packet, and transmit it to the host 900 through the external interface circuit 610.

The memory controller 630 may process the requests received from the CXL block 620 and transmit all data signals in a parallel form to the internal interface circuit 640 at the same time. For example, the memory controller 630 may include a Dynamic Random Access Memory (DRAM) controller. Also, the memory controller 630 may process all data signals of the parallel form provided from the internal interface circuit 640 and provide them to the CXL block 620.

The internal interface circuit 640 may relay a data write operation and a data read operation between the memory controller 630 and the memory media 700, and may adjust the timing of data transmission and reception. The internal interface circuit 640 may include a DFI-to-GIO interfacing circuit. The internal interface circuit 640 may transmit/receive data signals in a parallel form to/from the memory controller 630 according to the DDR PHY Interface (DFI), and may transmit/receive data signals in a parallel form to/from the memory media 700 according to global input/output (GIO). In other words, the internal interface circuit 640 may relay the parallel data signals on the DFI and the parallel data signals on the GIO. The data signals on the GIO may be the same as the data signals between the logic circuit and cell blocks in the memory device.

According to an embodiment of the present disclosure, the memory controller 630 and the memory media 700 may directly transmit/receive parallel data signals. In other words, the SERDES may not be disposed between the memory controller 630 and the memory media 700. Specifically, the parallel data signals (e.g., DFI signals) transmitted from the memory controller 630 to the memory media 700 may be transmitted as parallel data signals (e.g., GIO data signals) to the memory media 700, after transmission timing is adjusted in the internal interface circuit 640. Also, the parallel data signals (e.g., GIO data signals) transmitted from the memory media 700 to the memory controller 630 may be transmitted to the memory controller 630, after reception timing is adjusted in the internal interface circuit 640.

According to another embodiment of the present disclosure, the internal interface circuit 640 may be omitted. For example, the function of the internal interface circuit 640 may be embedded in the memory controller 630. In other words, the CXL controller 600 and the memory media 700 may transmit and receive all data signals in a parallel form. According to another embodiment of the present disclosure, the internal interface circuit 640 may be embedded in the memory media 700. Thus, the memory controller 630 and the memory media 700 may directly communicate with each other based on the DDR PHY interface (DFI).

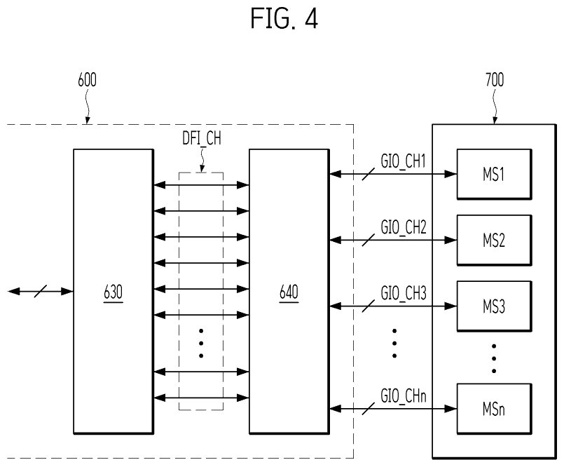

FIG. 3 is a block diagram schematically illustrating the memory media 700 in accordance with an embodiment of the present disclosure. Referring to FIG. 3, the memory media 700 may include at least one or more memory stack MS1 to MSn. The internal channels iCH may include branch channel sets bsCH1 to bsCHn. Each of the memory stacks MS1 to MSn may independently communicate with the CXL controller 600 through a corresponding branch channel set from among the branch channel sets bsCH1 to bsCHn. The branch channel sets bsCH1 to bsCHn may be parallel to each other. Each of the branch channel sets bsCH1 to bsCHn may transmit a chip select signal, a data strobe signal, command and address signals, and/or data signals from the internal interface circuit 640 to a corresponding memory stack from among the memory stacks MS1 to MSn. Each of the branch channel sets bsCH1 to bsCHn may transmit data signals from the corresponding memory stack, from among the memory stacks MS1 to MSn, to the internal interface circuit 640.

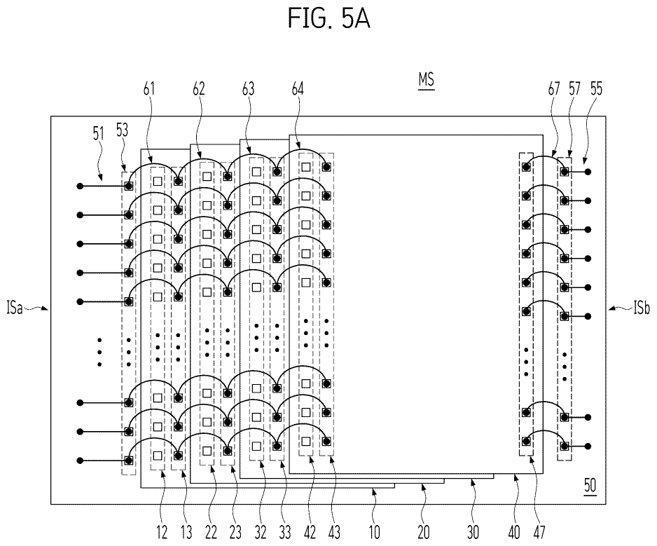

FIG. 4 is a block diagram schematically illustrating data channels DFI_CH, GIO_CH1-GIO_CHn for data communication in the memory system 800 in accordance with an embodiment of the present disclosure. Compared with FIG. 3, non-data signal channels are omitted. For example, chip select signal channels, data strobe signal channels, and/or other command and address signal channels may be omitted. In the CXL controller 600, the memory controller 630 and the internal interface circuit 640 may transmit/receive data through parallel DFI data channels DFI_CH. The internal interface circuit 640 of the CXL controller 600 and the memory stacks MS1 to MSn of the memory media 700 may transmit/receive data with each other through GIO data channel sets GIO_CH1 to GIO_CHn. The GIO data channel sets GIO_CH1 to GIO_CHn may be parts of the branch channel sets bsCH1 to bsCHn, respectively. Therefore, the GIO data channel sets GIO_CH1 to GIO_CHn may be parts of the internal channels iCH. The internal channels iCH may include the branch channel sets bsCH1 to bsCHn, and the branch channel sets bsCH1 to bsCHn may include the GIO data channel sets GIO_CH1 to GIO_CHn. A total number of the DFI data channels DFI_CH and a total number of the channels of the GIO data channel sets GIO_CH1 to GIO_CHn may be the same. For example, when the memory media 700 includes ten memory stacks MS1 to MS10, the total number of the DFI data channels DFI_CH may be ten times the total number of the GIO channels of each GIO data channel set GIO_CH1 to GIO_CHn. For example, when each of the GIO data channel sets GIO_CH1 to GIO_CHn has 4, 8, 16, 32, 64, 128, or 256 GIO channels, the total number of the DFI data channels DFI_CH may be 40, 80, 320, 640, 1280, or 2560. As mentioned above, the channels of the DFI data channels DFI_CH may be arranged in parallel and may electrically connect the memory controller 630 and the internal interface circuit 640 directly. The GIO channels of the GIO data channel sets GIO_CH1 to GIO_CHn may also be arranged in parallel and may electrically connect the internal interface circuit 640 and the memory stacks MS1 to MSn directly, respectively.

According to an embodiment of the present disclosure, as mentioned above, the branch channel sets bsCH1 to bsCHn may include GIO data channels GIO_CH1 to GIO_CHn, branch chip select signal channels, and branch data strobe signal channels, respectively.

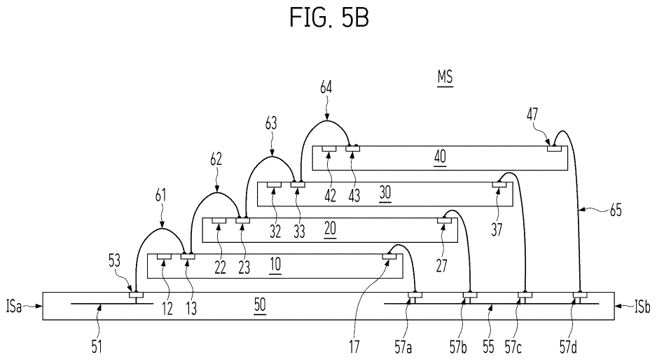

FIGS. 5A and 5B are top and side views schematically illustrating one memory stack MS in accordance with an embodiment of the present disclosure. For example, the memory stack MS illustrated in FIGS. 5A and 5B may be one from among memory stacks MS1 to MSn shown in FIG. 3 or FIG. 4. Referring to FIGS. 5A and 5B, the memory stack MS in accordance with the embodiment of the present disclosure may be mounted on a substrate 50. The memory stack MS may include a plurality of memory chips 10, 20, 30, and 40 that are stacked. For example, the memory stack MS may include first to fourth memory chips 10, 20, 30, and 40. For example, the memory stack MS may include a lower memory chip 10, intermediate memory chips 20 and 30, and an upper memory chip 40. The intermediate memory chips 20 and 30 may include an intermediate lower memory chip 20 and an intermediate upper memory chip 30. The first to fourth memory chips 10, 20, 30, and 40 may be homogeneous and identical. According to an embodiment of the present disclosure, it is assumed and illustrated that one memory stack MS has four memory chips 10, 20, 30 and 40. According to another embodiment of the present disclosure, the memory stack MS may include a stack of more than four memory chips for example, eight memory chips, 16 memory chips, 32 memory chips and so on.

The substrate 50 may include one of a silicon wafer, a silicon interposer, a Printed Circuit Board (PCB), or a glass substrate. The substrate 50 may include signal substrate interconnections 51, signal substrate pads 53, power substrate interconnections 55, and power substrate pads 57, 57a, 57b, 57c, and 57d. The substrate 50 may include a first substrate side ISa and a second substrate side ISb that are opposite to each other.

The signal substrate interconnections 51 may be disposed inside or on the surface of the substrate 50 to be closely adjacent to the first substrate side ISa. The signal substrate interconnections 51 may be electrically connected to the channels of one branch channel set from among the branch channel sets bsCH1 to bsCHn. In other words, the signal substrate interconnections 51 may correspond to one branch channel set from among the branch channel sets bsCH1 to bsCHn. According to an embodiment of the present disclosure, the signal substrate interconnections 51 may correspond to one GIO data channel set from among the GIO data channel sets GIO_CH1 to GIO_CHn. Therefore, the signal substrate interconnections 51 may be some of the GIO data channels.

The signal substrate pads 53 may be disposed close and adjacent to the first substrate side ISa to be disposed on the surface of the substrate 50. The signal substrate pads 53 may be electrically connected to the signal substrate interconnections 51, respectively. According to an embodiment of the present disclosure, the signal substrate pads 53 may be bond fingers for wire bonding.

The power substrate interconnections 55 may be disposed close and adjacent to the second substrate side ISb to be disposed inside or on the surface of the substrate 50. The first substrate side ISa and the second substrate side ISb may be opposite to each other. The power substrate interconnections 55 may not be coupled to the signal substrate interconnections 51, i.e., the GIO data channels. For example, the power substrate interconnections 55 may be electrically connected to the power interconnections that are electrically and physically separated from the signal substrate interconnections 51.

The power substrate pads 57, 57a, 57b, 57c, and 57d may be disposed close and adjacent to the second substrate side ISb of the substrate 50 to be disposed on the surface of the substrate 50. The power substrate pads 57, 57a, 57b, 57c, and 57d may include a first power substrate pad 57a electrically connected to the first memory chip 10, a second power substrate pad 57b electrically connected to the second memory chip 20, a third power substrate pad 57c electrically connected to the third memory chip 30, and a fourth power substrate pad 57d electrically connected to the fourth memory chip 40. The power substrate pads 57, 57a, 57b, 57c, and 57d may be electrically connected to the power substrate interconnections 55. The power substrate pads 57, 57a, 57b, 57c, and 57d may be bond fingers for wire bonding. The power substrate interconnections 55 and the power substrate pads 57, 57a, 57b, 57c, and 57d may selectively transmit various powers, such as VDD, VCC, VDDi, VDDiQ, Vref, VPP_EXT, and VSS.

The first to fourth memory chips 10, 20, 30, and 40 may be arranged as a staircase offset-stacked in a direction from the first substrate side ISa to the second substrate side ISb. The memory chips 10, 20, 30 and 40 may include first to fourth outer chip pads 12, 22, 32, and 42, first to fourth inner chip pads 13, 23, 33, and 43, and first to fourth power chip pads 17, 27, 37, and 47, respectively. According to an embodiment of the present disclosure, the first to fourth outer chip pads 12, 22, 32, and 42 may be disposed adjacent to first chip sides of the first to fourth memory chips 10, 20, 30, and 40 that are closer to the first substrate side ISa to form a first row, i.e., an outer row. Furthermore, the first to fourth inner chip pads 13, 23, 33, and 43 may be disposed adjacent to the first chip sides of the first to fourth memory chips 10, 20, 30, and 40 and the first to fourth outer chip pads 12, 22, 32, and 42 respectively to form a second row, i.e., an inner chip row. In other words, the first to fourth outer chip pads 12, 22, 32, and 42 may be disposed closer to the first chip sides of the first to fourth memory chips 10, 20, 30, and 40 than the first to fourth inner chip pads 13, 23, 33, and 43. The first to fourth inner chip pads 13, 23, 33, and 43 may be disposed further from the first chip sides of the first to fourth memory chips 10, 20, 30, and 40 than the first to fourth outer chip pads 12, 22, 32, and 42.

The first to fourth outer chip pads 12, 22, 32, and 42 of the first to fourth memory chips 10, 20, 30, and 40 may be electrically disabled or electrically floated. For example, the first to fourth outer chip pads 12, 22, 32, and 42 of the first to fourth memory chips 10, 20, 30, and 40 may not be physically and directly coupled to bonding wires or other components having an electrical interconnection function. The first to fourth outer chip pads 12, 22, 32, and 42 may be electrically connected to a logic circuit block, for example, a peripheral circuit block, of the first to fourth memory chips 10, 20, 30, and 40 respectively corresponding thereto. The logic circuit block may include a SERDES(serializer/de-serializer), a command signal processing circuit, an address circuit, and a clock circuit. Accordingly, the logic circuit blocks inside of each of the first to fourth memory chips 10, 20, 30, and 40 may be disabled.

The first to fourth inner chip pads 13, 23, 33, and 43 of the first to fourth memory chips 10, 20, 30, and 40 may be coupled to the signal substrate pads 53 through the first to fourth bonding wires 61 to 64. For example, one signal substrate pad 53 may be electrically connected in a cascade form to all of the first to fourth inner chip pads 13, 23, 33, and 43 of the first to fourth memory chips 10, 20, 30, and 40 that are arranged in the same direction. Since the signal substrate interconnections 51 and the signal substrate pads 53 transmit parallel global input/output data signals, the first to fourth inner chip pads 13, 23, 33, and 43 of the first to fourth memory chips 10, 20, 30, and 40 may be commonly coupled to a corresponding signal substrate pads 53. The first inner chip pads 13 of the lowermost first memory chip 10 directly disposed over the substrate 50 may be directly and electrically connected to the signal substrate pads 53 on a 1:1 basis. The second inner chip pads 23 of the second memory chip 20, which is stacked over the first memory chip 10, may be directly and electrically connected to corresponding first inner chip pads 13 of the first memory chip 10 on a 1:1 basis. The third inner chip pads 33 of the third memory chip 30, which is stacked over the second memory chip 20, may be directly and electrically connected to corresponding second inner chip pads 23 of the second memory chip 20 on a 1:1 basis. The fourth inner chip pads 43 of the fourth memory chip 40, which is stacked over the third memory chip 30, may be directly and electrically connected to corresponding third inner chip pads 33 of the third memory chip 30 on a 1:1 basis.

According to an embodiment of the present disclosure (not illustrated), some of the first to fourth outer chip pads 12, 22, 32, and 42 may be electrically connected to the signal substrate pad 53. For example, some of the first to fourth outer chip pads 12, 22, 32, and 42 may be electrically connected to the signal substrate pad 53 to transmit chip select signals. According to another embodiment of the present disclosure, some of the first to fourth outer chip pads 12, 22, 32, and 42 may not be electrically connected to the signal substrate pad 53, and some of the first to fourth inner chip pads 13, 23, 33, and 43 may be used to transmit chip select signals.

The first to fourth power chip pads 17, 27, 37, and 47 of the first to fourth memory chips 10, 20, 30, and 40 may be disposed close and adjacent to the second substrate side ISb and may be electrically connected to the power substrate pads 57 through power interconnections 65, respectively. The first to fourth power chip pads 17, 27, 37, and 47 of the first to fourth memory chips 10, 20, 30, and 40 may be disposed close and adjacent to second chip sides of the first to fourth memory chips 10, 20, 30, and 40, where the second chip sides are opposite to the first chip sides of the first to fourth memory chips 10, 20, 30, and 40. The first power chip pads 17 may be electrically connected to the first power substrate pads 57a, the second power chip pads 27 may be electrically connected to the second power substrate pads 57b, the third power chip pads 37 may be electrically connected to the third power substrate pads 57c, and fourth power chip pads 47 may be electrically connected to the fourth power substrate pads 57d.

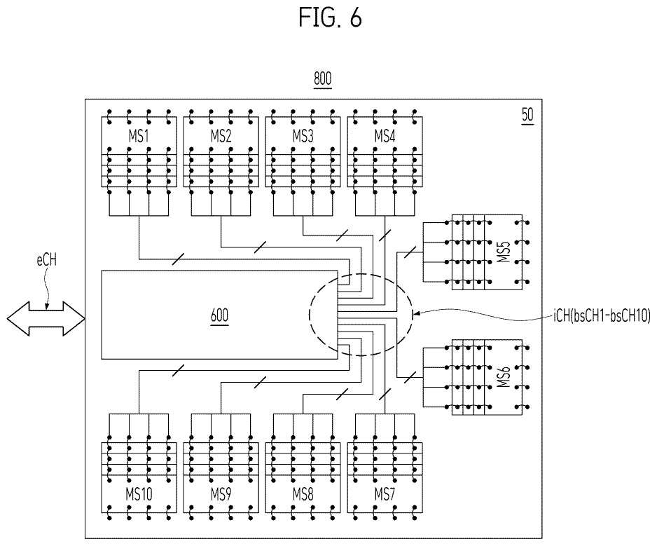

FIG. 6 is a circuit diagram schematically illustrating a memory system 800 in accordance with an embodiment of the present disclosure. The memory system 800 may be provided in a module form in the electronic system 1000. In other words, the memory system 800 may be a memory module.

Referring to FIG. 6, the memory system 800 may include the CXL controller 600, the plurality of memory stacks MS1 to MS10, and the internal channels iCH that are disposed over the substrate 50. According to an embodiment of the present disclosure, ten memory stacks MS1 to MS10 are illustrated as an example in FIG. 6. Each of the memory stacks MS1 to MS10 may include a plurality of memory chips (e.g., 10, 20, 30, and 40 of FIGS. 5A and 5B) that are offset-stacked in a staircase. According to an embodiment of the present disclosure, a stack of four memory chips is schematically illustrated in FIG. 6. According to another embodiment of the present disclosure, each of the memory stacks MS1 to MS10 may include eight or more memory chips (not illustrated). As illustrated in FIG. 6, the arranged chip pads (e.g., the inner chip pads 13, 23, 33, and 43 of FIGS. 5A and 5B) of the memory chips included in one memory stack, from among the memory stacks MS1 to MS10, may be coupled to each other in a cascade form. The inner channel iCH may include the plurality of branch channel sets (see FIG. 4) respectively corresponding to the memory stacks MS1 to MS10. Each of the memory stacks MS1 to MS10 may communicate with the CXL controller 600 independently and in parallel through the branch channel sets bsCH1 to bsCH10.

The memory system 800 may communicate with a host (e.g., a host 900 of FIG. 1) through the external channel eCH, that is, the CXL channel.

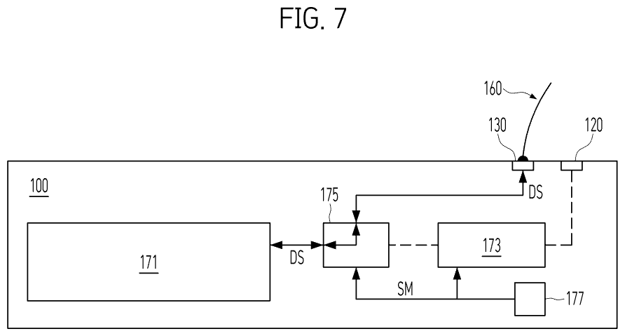

FIG. 7 illustrates a memory chip 100 operating in a slave mode in accordance with embodiments of the present disclosure. The memory chip 100 may be one from among the first to fourth memory chips 10, 20, 30, and 40 described above with reference to FIGS. 5A and 5B.

Referring to FIG. 7, the memory chip 100 may include a cell block 171, a logic circuit block 173, a buffer block 175, and a mode setting block 177. An outer chip pad 120 and an inner chip pad 130 may be disposed over the memory chip 100.

The cell block 171 may include memory cells for storing data. The logic circuit block 173 may include peripheral circuits for processing command signals and data signals.

The buffer block 175 may be disposed between the cell block 171 and the logic circuit block 173. According to an embodiment of the present disclosure, the buffer block 175 may be a part of the cell block 171. For example, the buffer block 175 may be an input/output buffer circuit TX/RX integrated with the cell block 171. According to an embodiment of the present disclosure, the buffer block 175 may be a part of the logic circuit block 173. For example, the buffer block 175 may be an input/output buffer circuit TX/RX integrated into the logic circuit block 173.

The mode setting block 177 may generate a slave mode signal SM for the memory chip 100 to operate in a slave mode. According to an embodiment of the present disclosure, the mode setting block 177 may include a fuse circuit so that the generated signal is always a slave mode signal SM. The mode setting block 177 may generate the slave mode signal SM and provide it to the buffer block 175. The buffer block 175 that receives the slave mode signal SM may electrically connect the inner chip pad 130 and the cell block 171. In other words, data signals DS may be transmitted and received directly between the inner chip pad 130 and the cell block 171 without going through the logic circuit block 173.

The slave mode signal SM provided from the mode setting block 177 may disable the logic circuit block 173. Therefore, the logic circuit block 173 and the buffer block 175 may not transmit/receive electrical signals. The outer chip pad 120 electrically connected to the logic circuit block 173 may also be disabled and float. In other words, the outer chip pad 120 may not be coupled to a wire and may float. In FIG. 7, the disabled signal paths are indicated by a dotted line.

According to another embodiment of the present disclosure, a chip recognition signal may be provided to the mode setting block 177 through at least one from among multiple inner chip pads 130, and the mode setting block 177 may generate a slave mode signal SM according to the chip recognition signal. The chip recognition signal may be provided from a memory controller (e.g., 630 of FIG. 4) to at least one among the inner chip pads 130.

According to embodiments of the present disclosure, since a memory controller and a memory media directly communicate data through channels that are arranged in parallel, it is possible to provide a memory system with reduced power consumption, faster operation speed, and reduced occupying area.

According to embodiments of the present disclosure, since a memory system using only a cell area of a general memory chip is provided, additional memory design cost are not incurred.

According to embodiments of the present disclosure, since a memory chip having a logic circuit block may be operated in a slave mode, the application flexibility of the memory chip may be improved.

While the present disclosure has been described with respect to the specific embodiments, it will be apparent to those skilled in the art that various changes and modifications may be made without departing from the spirit and scope of the disclosure as defined in the following claims.

What is claimed is:

1. A memory system, comprising:
a substrate having a first substrate side and a second substrate side, that is opposite to the first substrate side; and
a memory media including a first memory stack mounted over the substrate,
wherein:
the substrate includes first signal substrate pads disposed over a surface of the substrate, wherein the first signal substrate pads are closer to the first substrate side than the second substrate side,
the first memory stack includes a first memory chip and a second memory chip that is offset-stacked over the first memory chip,
the first memory chip includes first outer chip pads and first inner chip pads, wherein the first outer chip pads and first inner chip pads are disposed adjacent to a first chip side of the first memory chip, wherein the first chip side of the first memory chip is closer to the first substrate side than the second substrate side,
the first outer chip pads are disposed closer to the first chip side of the first memory chip than the first inner chip pads,
the second memory chip includes second outer chip pads and second inner chip pads, wherein the second outer chip pads and the second inner chip pads are disposed adjacent to a first chip side of the second memory chip, wherein the first chip side of the second memory chip is closer to the first substrate side than the second substrate side, and
the second outer chip pads are disposed closer to the first chip side of the second memory chip than the second inner chip pads, and
the corresponding first signal substrate pads, the corresponding first inner chip pads, and the corresponding second inner chip pads are electrically connected to each other.

2. The memory system of claim 1, wherein the first outer chip pads and the second outer chip pads are floating.

3. The memory system of claim 1,
wherein the first memory stack includes:
a third memory chip that is offset-stacked over the second memory chip; and
a fourth memory chip that is offset-stacked over the third memory chip, and
wherein the third memory chip includes third outer chip pads and third inner chip pads, wherein the third outer chip pads and the third inner chip pads are disposed adjacent to a first chip side of the third memory chip closer to the first substrate side than the second substrate side,
wherein the third outer chip pads are disposed closer to the first chip side of the third memory chip than the third inner chip pads,
wherein the fourth memory chip includes fourth outer chip pads and fourth inner chip pads, wherein the fourth outer chip pads and the fourth inner chip pads are disposed adjacent to a first chip side of the fourth memory chip adjacent to the first substrate side,
wherein the fourth outer chip pads are disposed closer to the first chip side of the fourth memory chip than the fourth inner chip pads,
wherein the corresponding signal substrate pads, the corresponding first inner chip pads, the corresponding second inner chip pads, the corresponding third inner chip pads, and the corresponding fourth inner chip pads are electrically connected.

4. The memory system of claim 3, wherein the third outer chip pads and the fourth outer chip pads are floating.

5. The memory system of claim 3,
wherein the substrate further includes first to fourth power substrate pads disposed on the surface of the substrate adjacent to the second substrate side,
wherein the first memory chip further includes first power chip pads that are disposed adjacent to a second chip side of the first memory chip, which is opposite to the first chip side of the first memory chip,
wherein the second memory chip further includes second power chip pads that are disposed adjacent to a second chip side of the second memory chip, which is opposite to the first chip side of the second memory chip,
wherein the third memory chip further includes third power chip pads that are disposed adjacent to a second chip side of the third memory chip, which is opposite to the first chip side of the third memory chip,
wherein the fourth memory chip further includes fourth power chip pads that are disposed adjacent to a second chip side of the fourth memory chip, which is opposite to the first chip side of the fourth memory chip,
wherein the first power substrate pads are electrically connected to the first power chip pads,
wherein the second power substrate pads are electrically connected to the second power chip pads,
wherein the third power substrate pads are electrically connected to the third power chip pads, and
wherein the fourth power substrate pads are electrically connected to the fourth power chip pads.

6. The memory system of claim 1, further comprising:
a memory controller;
an interface circuit;
first parallel data channels between the memory controller and the interface circuit; and
second parallel data channels between the interface circuit and the memory media.

7. The memory system of claim 6,
wherein the first parallel data channels include DDR PHY interface (DFI) channels, and
wherein the second parallel data channels include global input/output (GIO) channels.

8. The memory system of claim 6,
wherein the memory media further includes a second memory stack mounted over the substrate,
wherein the substrate includes second signal substrate pads exposed on the surface of the substrate adjacent to the first substrate side, and
wherein the second signal substrate pads are electrically connected to the second memory stack.

9. The memory system of claim 8,
wherein the substrate further includes first signal substrate interconnections and second signal substrate interconnections,
wherein the first signal substrate interconnections are electrically connected to the corresponding first signal substrate pads,
wherein the second signal substrate interconnections are electrically connected to the corresponding second signal substrate pads,
wherein the second parallel data channels include a first set of second parallel data channels and a second set of second parallel data channels,
wherein the first signal substrate interconnections are electrically connected to the first set of the second parallel data channels, and
wherein the second signal substrate interconnections are electrically connected to the second set of the second parallel data channels.

10. The memory system of claim 9, wherein a number of the first parallel data channels is equal to a sum of a number of the second parallel data channels in the first set of the second parallel data channels and a number of the second parallel data channels in the second set of the second parallel data channels.

11. A memory system, comprising:
a memory controller;
an interface circuit;
DDR PHY Interface (DFI) channels between the memory controller and the interface circuit;
a memory media; and
global input/output (GIO) channels between the interface circuit and the memory media,
wherein the memory media includes a first memory stack and a second memory stack that are mounted over a substrate,
wherein each of the first memory stack and the second memory stack includes a first memory chip and a second memory chip that are offset-stacked over the substrate,
wherein the substrate includes:
first signal substrate interconnections and second signal substrate interconnections electrically connected to the GIO channels, respectively;
first signal substrate pads electrically connected to the first signal substrate interconnections; and
second signal substrate pads electrically connected to the second signal substrate interconnections, and
wherein each of the first and second memory chips includes:
outer chip pads and inner chip pads that are disposed adjacent to a first chip side of each of the first and second memory chips, wherein the outer chip pads are closer to the first chip side of each of the first and second memory chips than the inner chip pads,
wherein the first signal substrate pads are electrically connected to the inner chip pads of the first and second memory chips of the first memory stack, and
wherein the second signal substrate pads are electrically connected to the inner chip pads of the first and second memory chips of the second memory stack.

12. The memory system of claim 11, wherein each of the DFI channels and the GIO channels includes a plurality of data channels that are coupled in parallel.

13. The memory system of claim 11, wherein a number of the DFI channels and a number of the GIO channels are the same.

14. The memory system of claim 13,
wherein the GIO channels include:
a first set of the GIO channels electrically connected to the first memory stack, and
a second set of the GIO channels electrically connected to the second memory stack.

15. The memory system of claim 11, wherein the outer chip pads of each of the first and second memory chips are floating.

16. The memory system of claim 11,
wherein the substrate further includes power substrate pads,
wherein the first and second memory chips further include power chip pads that are disposed adjacent to a second chip side of each of the first and second memory chips, wherein the second chip side is opposite to the first chip side, and
wherein the power substrate pads are electrically connected to the power chip pads.

17. The memory system of claim 11,
wherein the first memory chip includes:
a first lower memory chip;
a first intermediate memory chip that is offset-stacked over the first lower memory chip; and
a first upper memory chip that is offset-stacked over the first intermediate memory chip,
wherein the outer chip pads include:
first lower outer chip pads that are disposed adjacent to a first chip side of the first lower memory chip;
first intermediate outer chip pads that are disposed adjacent to a first chip side of the first intermediate memory chip; and
first upper outer chip pads that are disposed adjacent to a first chip side of the first upper memory chip,
wherein the inner chip pads include:
first lower inner chip pads that are disposed adjacent to the first lower outer chip pads, wherein the first lower outer chip pads are closer to the first chip side of the first lower memory chip than the first lower inner chip pads;
first intermediate inner chip pads that are disposed adjacent to the first intermediate outer chip pads, wherein the first intermediate outer chip pads are closer to the first chip side of the first intermediate memory chip than the first intermediate inner chip pads; and
first upper inner chip pads that are disposed adjacent to the first upper outer chip pads, wherein the first upper outer chip pads are closer to the first chip side of the first upper memory chip than the first upper inner chip pads,
wherein the corresponding first signal substrate pads, the corresponding first lower inner chip pads, the corresponding first intermediate inner chip pads, and the corresponding first upper inner chip pads are electrically connected.

18. The memory system of claim 17,
wherein the second memory chip includes:
a second lower memory chip;
a second intermediate memory chip, which is offset-stacked over the second lower memory chip; and
a second upper memory chip, which is offset-stacked over the second intermediate memory chip,
wherein the outer chip pads include:
second lower outer chip pads that are disposed adjacent to a first chip side of the second lower memory chip;
second intermediate outer chip pads that are disposed adjacent to a first chip side of the second intermediate memory chip; and
second upper outer chip pads that are disposed adjacent to a first chip side of the second upper memory chip,
wherein the inner chip pads include:
second lower inner chip pads that are disposed adjacent to the second lower outer chip pads, wherein the second lower outer chip pads are closer to the first chip side of the second lower memory chip than the second lower inner chip pads;
second intermediate inner chip pads that are disposed adjacent to the second intermediate outer chip pads, wherein the second intermediate outer chip pads are closer to the first chip side of the second intermediate memory chip than the second intermediate inner chip pads; and
second upper inner chip pads that are disposed adjacent to the second upper outer chip pads, wherein the second upper outer chip pads are closer to the first chip side of the second upper memory chip than the second upper inner chip pads,
wherein the corresponding second signal substrate pads, the corresponding second lower inner chip pads, the corresponding second intermediate inner chip pads, and the corresponding second upper inner chip pads are electrically connected.
